(19) United States
(12) Patent Application Publication
(10) Pub. No.: US 2026/0143797 A1
(43) Pub. Date: May 21, 2026

(54) SEMICONDUCTOR DEVICES

(71) Applicant: Samsung Electronics Co., Ltd., Suwon-si (KR)

(72) Inventors: Sunggyu HAN, Suwon-si (KR); Heonjong SHIN, Suwon-si (KR); Seowoo NAM, Suwon-si (KR); Hyeyoung PARK, Suwon-si (KR); Dowon SONG, Suwon-si (KR); Junkyu JUNG, Suwon-si (KR)

(21) Appl. No.: 19/214,471

(22) Filed: May 21, 2025

(30) Foreign Application Priority Data
Nov. 18, 2024 (KR) 10-2024-0164491

(51) Int. Cl. H10D 84/83; H01L 23/522; H01L 23/528; H10D 30/00; H10D 30/01; H10D 30/43; H10D 62/10; H10D 62/13; H10D 62/60; H10D 64/23; H10D 84/01

(52) U.S. Cl. CPC H10D 84/832; H10D 30/43; H10D 30/502; H10D 62/102; H10D 62/121; H10D 62/151; H10D 62/60; H10D 64/256; H10D 84/8312; H10W 20/42; H10W 20/435; H10W 20/498; H10D 30/014; H10D 30/0191; H10D 84/0149

(57) ABSTRACT

Provided is a semiconductor device including a base pattern; channel patterns on an upper surface of the base pattern; a gate structure on the upper surface of the base pattern; a first source/drain pattern on a first side of the gate structure; a second source/drain pattern on a second side of the gate structure; a first source/drain liner between the first source/drain pattern and the gate structure; a second source/drain liner between the second source/drain pattern and the gate structure; and a backside plug in the base pattern, wherein the backside plug is electrically connected to the first source/drain pattern, wherein an upper end of the first source/drain liner is between the first source/drain pattern and the gate structure, and wherein a lower end of the first source/drain liner is between the upper surface of the base pattern and a lower surface of the base pattern.

### CROSS-REFERENCE TO RELATED APPLICATIONS

This application claims the benefit of Korean Patent Application No. 10-2024-0164491, filed on Nov. 18, 2024, in the Korean Intellectual Property Office, the disclosure of which is incorporated herein by reference in its entirety.

### BACKGROUND OF THE INVENTION

Example embodiments relate to semiconductor devices. As one of the scaling technologies to increase the density of semiconductor devices, proposed is a multi-gate transistor in which a multi-channel active pattern (or silicon body) in the shape of a fin or nanowire is formed on the substrate and a gate is formed on the multi-channel active pattern surface.

Meanwhile, in order to address the routing complexity that occurs on the frontside of the field-effect transistor and to prevent excessive voltage drop, introduced is a backside power distribution network (BSPDN), at least a portion of a back-end of line (BEOL) is formed on the backside of the field-effect transistor.

Semiconductor devices may need to be manufactured reliably to meet the superior performance demands of consumers. However, as semiconductor devices become more highly integrated, the possibility of short circuits or leakage currents may increase.

### SUMMARY OF THE INVENTION

An aspect of the current inventive concepts may provide a semiconductor device that reduces (e.g., prevents) short circuits that may occur between the gate structure and the backside plug by placing a part of the source/drain region (e.g., the source/drain liner) between the backside plug and the gate structure.

The technical tasks to be achieved by the present example embodiments are not limited to the technical tasks described above, and other technical tasks may be inferred from the following example embodiments by those skilled in the art.

According to an aspect, there is provided a semiconductor device including a base pattern; channel patterns on a frontside of the base pattern corresponding to an upper surface of the base pattern, wherein the channel patterns are spaced apart from each other in a first direction that is perpendicular to the upper surface of the base pattern; a gate structure on the upper surface of the base pattern, wherein the gate structure comprises a gate insulating film and a gate electrode, and at least a portion of the gate structure is between adjacent ones of the channel patterns; a first source/drain pattern on a first side of the gate structure; a second source/drain pattern on a second side of the gate structure that is opposite to the first side of the gate structure in a second direction that intersects the first direction, wherein the second direction is parallel with the upper surface of the base pattern; a first source/drain liner between the first source/drain pattern and the gate structure in the second direction; a second source/drain liner between the second source/drain pattern and the gate structure in the second direction; a backside plug in the base pattern, wherein the backside plug is electrically connected to the first source/drain pattern; and a place holder in the base pattern, wherein the place holder is on an inner side of the second source/drain liner, wherein an upper end of the first source/drain liner is between the first source/drain pattern and the gate structure in the second direction, and a lower end of the first source/drain liner is between the upper surface of the base pattern and a backside of the base pattern, corresponding to a lower surface of the base pattern that is opposite to the upper surface of the base pattern in the first direction, and wherein the upper end of the first source/drain liner is opposite to the lower end of the first source/drain liner in the first direction.

According to an aspect, there is provided a semiconductor device including a base pattern; channel patterns on a frontside of the base pattern, corresponding to an upper surface of the base pattern, wherein the channel patterns are spaced apart from each other in a first direction that is perpendicular to the upper surface of the base pattern; a gate structure on the upper surface of the base pattern, wherein the gate structure comprises a gate insulating film and a gate electrode, and at least a portion of the gate structure is between adjacent ones of the channel patterns; a first source/drain pattern on a first side of the gate structure; a first source/drain liner between the first source/drain pattern and the gate structure in a second direction that is parallel with the upper surface of the base pattern; and a backside plug between a backside of the base pattern, corresponding to a lower surface of the base pattern, and the first source/drain pattern in the first direction, wherein the lower surface of the base pattern is opposite to the upper surface of the base pattern in the first direction, wherein the backside plug is electrically connected to the first source/drain pattern, wherein the backside plug is in contact with the base pattern, and wherein the first source/drain liner extends along a side wall of the gate structure and extends into the base pattern in the first direction.

According to an aspect, there is provided a semiconductor device including a base pattern; channel patterns on a frontside of the base pattern, corresponding to an upper surface of the base pattern, wherein the channel patterns are spaced apart from each other in a first direction that is perpendicular to the upper surface of the base pattern; a gate structure on the upper surface of the base pattern,, wherein the gate structure is between adjacent ones of the channel patterns; a first source/drain pattern on a first side of the gate structure; a second source/drain pattern on a second side of the gate structure that is opposite to the first side of the gate structure in a second direction that is parallel with the upper surface of the base pattern; a backside plug underneath the first source/drain pattern, wherein the backside plug is electrically connected to the first source/drain pattern; a place holder underneath the second source/drain pattern, wherein the place holder is electrically connected to the second source/drain pattern; a first source/drain liner between the first source/drain pattern and the gate structure in the second direction; and a second source/drain liner between the second source/drain pattern and the gate structure in the second direction, wherein the first source/drain liner overlaps the backside plug in the second direction.

Additional aspects of example embodiments will be set forth in part in the description which follows and, in part, will be apparent from the description, or may be learned by practice of the disclosure.

According to example embodiments, the possibility of short circuits or currents leakage occurring between components of a semiconductor device may be reduced.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a layout drawing of a semiconductor device according to an example embodiment;

FIG. 2 is a drawing illustrating a cross-section taken along line A-A′ of FIG. 1;

FIGS. 3 to 16 are drawings illustrating intermediate operations for explaining a method of manufacturing a semiconductor device according to an example embodiment; and

FIGS. 17 to 19 are drawings illustrating intermediate operations for explaining a method of manufacturing a semiconductor device according to an example embodiment.

### DETAILED DESCRIPTION

Terms or words used in the specification and claims may not be limited to their dictionary meanings. The terms or words may be interpreted with meaning and concept consistent with the technical area of the present disclosure. The example embodiments described in this specification and the configurations shown in the drawings are only the example embodiments of the present disclosure. Accordingly, there may be various equivalents and modifications.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” “may include”, “comprise”, and “may comprise” as used herein indicate the presence of corresponding features (for example, elements such as numerical values, functions, operations, or parts), and do not preclude the presence of additional features. The term “and/or” includes any and all combinations of one or more of the associated listed items.

Terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, terms such as an upper side, top, a lower side, bottom, a side, front and a back side may be expressed based on the direction shown in the drawing. If the direction of the object changes, it may be expressed differently.

Hereinafter, example embodiments according to the technical idea of the present disclosure will be described with reference to the attached drawings.

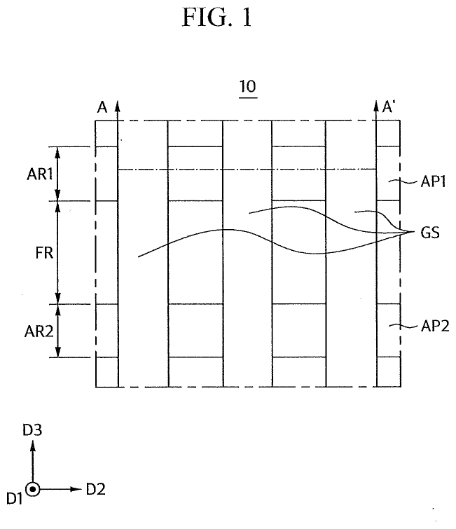

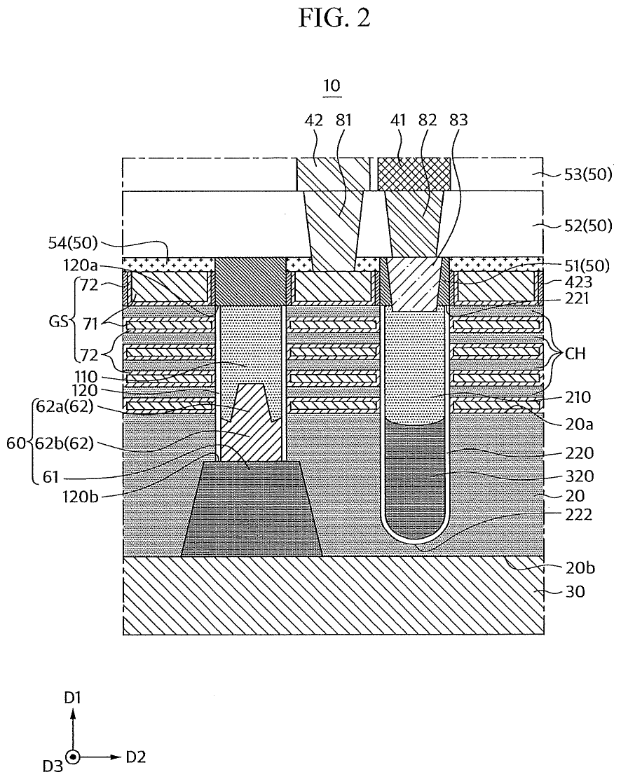

FIG. 1 is a layout drawing of a semiconductor device 10 according to an example embodiment, and FIG. 2 is a drawing illustrating a cross-section taken along line A-A′ of FIG. 1.

Referring to FIG. 1 and FIG. 2, the semiconductor device 10 may include a first active region AR1, a second active region AR2 and a field region FR.

According to some example embodiments, the first direction D1 may indicate a direction perpendicular to a frontside 20a (e.g., a front surface or an upper surface) of a base pattern 20. The second direction D2 may indicate the direction intersecting the first direction D1. The second direction D2 may be parallel with the frontside 20a (e.g., the front surface or the upper surface) of the base pattern 20. The third direction D3 may indicate a direction intersecting with the first direction D1 and the second direction D2. The third direction D3 may be parallel with the frontside 20a (e.g., the front surface or the upper surface) of the base pattern 20. The first direction D1 and the second direction D2 may be perpendicular to each other, the second direction D2 and the third direction D3 may be perpendicular to each other, and the third direction D3 and the first direction D1 may be perpendicular to each other.

According to some example embodiments, the first active region AR1 and the second active region AR2 may each extend in the second direction D2. The first active region AR1 and the second active region AR2 may be spaced apart from each other in the third direction D3. The first active region AR1 and the second active region AR2 may be separated by the field region FR.

According to some example embodiments, the field region FR may be placed between the first active region AR1 and the second active region AR2 (in the third direction D3). The field region FR may border the first active region AR1 and the second active region AR2. The field region FR may have a shallow trench isolation (STI) structure. However, example embodiments of the present disclosure are not limited thereto. For example, the field region FR may have (e.g., may be defined by) a deep trench.

According to some example embodiments, a device separator (not illustrated) may be placed around (adjacent) the first active region AR1 and the second active region AR2. The portion between the first active region AR1 and the second active region AR2 of the device separator may be the field region FR. For example, the part where the channel region of a transistor, which may be an example of the semiconductor device 10, is formed may be the active region, and the part that separates the channel region of the transistor formed in the active region may be the field region FR. The active region may be the part where a fin-type pattern or a nano sheet is formed, which is used as the channel region of the transistor, and the field region FR may be a region where a fin-type pattern or a nano sheet is not formed.

According to some example embodiments, the first active region AR1 and the second active region AR2 may be p-channel metal-oxide-semiconductor (PMOS) forming regions. However, example embodiments of the present disclosure are not limited thereto. For example, the first active region AR1 and the second active region AR2 may be n-channel metal-oxide semiconductor (NMOS) forming regions. For example, one of the first active region AR1 and the second active region AR2 may be a PMOS forming region, and the other one may be a NMOS forming region.

According to some example embodiments, the semiconductor device 10 may include a fin field-effect transistor and/or a nano sheet field-effect transistor, but example embodiments of the present disclosure are not limited thereto. The semiconductor device 10 illustrated in the drawing is only an example embodiment and is not limited thereto.

According to some example embodiments, the semiconductor device 10 may include, for example, a tunneling transistor (a tunneling field effect transistor (FET)), a three-dimensional transistor, and/or a vertical transistor (a vertical FET). In some embodiments, the semiconductor device 10 may include a planar transistor. The semiconductor device 10 may be applied to a transistor based on a two-dimensional material (a 2D material based FET) and its heterostructure. The semiconductor device 10 according to an example may include a bipolar junction transistor and/or a lateral double-diffusion transistor (LDMOS).

The semiconductor device 10 according to some example embodiments may include the base pattern 20, a plurality of channel patterns CH, a gate structure GS, a first source/drain pattern 110, a second source/drain pattern 210, a frontside plug (a frontside wiring via 82 and a frontside contact 83), a backside plug 60, a frontside wiring pattern 41 and a backside wiring pattern 30.

According to some example embodiments, the base pattern 20 may be placed on the backside wiring pattern 30. The base pattern 20 may be placed between the backside wiring pattern 30 and the gate structure(s) GS (in the first direction D1).

According to some example embodiments, the base pattern 20 may include a semiconductor material. For example, the base pattern 20 may include silicon or silicon-on-insulator (SOI). In some embodiments, the base pattern 20 may include, but is not limited to, silicon germanium, silicon germanium on insulator (SGOI), indium antimonide, lead telluride, indium arsenide, indium phosphide, gallium arsenide, and/or gallium antimonide. For example, the base pattern 20 may include silicon oxide, silicon nitride, silicon oxycarbide, silicon oxynitride, and/or a low-k material.

According to some example embodiments, the base pattern 20 may extend in the second direction D2. A device insulator may be disposed between two base patterns 20 spaced apart in the third direction D3. The base pattern 20 may have a pin shape. According to some example embodiments, the base pattern 20 and the device insulator may include the same insulating material. In this case, the boundary between the base pattern 20 and the device insulator may not be discernible, and the base pattern 20 and the device insulator may be regarded as one insulating layer. For example, the base pattern 20 and the device insulator may be connected to form an integrated (a monolithic) structure.

According to some example embodiments, a plurality of channel patterns CH may be placed on (a front side, a front surface, or an upper surface of) the base pattern 20. The plurality of channel patterns CH may be spaced apart from the base pattern 20 in the first direction D1. The plurality of channel patterns CH may be arranged on the frontside 20a (e.g., the front surface or the upper surface) of the base pattern 20. Ones of the plurality of channel patterns CH may be spaced apart from each other in the first direction D1.

The drawing illustrates the plurality of channel patterns CH including four nano sheets, but the drawing is for convenience of explanation only, and example embodiments of the present disclosure are not limited thereto. For example, the plurality of channel patterns CH may include one, two, three, or more than four nano sheet(s).

According to some example embodiments, the plurality of channel patterns CH may have a gate electrode 71 and a gate insulating film 72 disposed between each of the channel patterns CH. For example, the gate electrode 71 and the gate insulating film 72 may be between adjacent ones of the plurality of channel patterns CH (in the first direction D1). Although not illustrated, the gate insulating film 72 may be placed on the uppermost channel pattern among the plurality of channel patterns CH. The gate electrode 71 may be on the uppermost one of the plurality of channel patterns CH. A gate spacer 423 may be on the uppermost one of the plurality of channel patterns CH. The gate spacer 423 may extend around (e.g., at least partially surround) the uppermost one of the gate electrodes 71. For example, the gate spacer 423 may be on a lower surface and a side surface of the uppermost one of the gate electrodes 71.

According to some example embodiments, the plurality of channel patterns CH may include an elemental semiconductor material such as silicon or germanium. In some embodiments, the plurality of channel patterns CH may include a compound semiconductor. For example, the plurality of channel patterns CH may include a group IV-IV compound semiconductor and/or a group III-V compound semiconductor. For example, the group IV-IV compound semiconductor may be a binary compound, a ternary compound, or a compound doped with a group IV element of these elements, including, for example, carbon, silicon, germanium and/or tin. For example, the group III-V compound semiconductor may be a binary compound, a ternary compound, or a quaternary compound formed by combining, for example, aluminum, gallium, and/or indium, which are Group III elements, with, for example, phosphorus, arsenic and/or antimony, which are Group V elements.

According to some example embodiments, the gate structure(s) GS may be placed on the frontside 20a (e.g., the front surface or the upper surface) of the base pattern 20. The semiconductor device 10 may include a plurality of gate structures GS. Each of the plurality of gate structures GS may extend in the third direction D3. The gate structures GS may be placed on the first active pattern AP1 and the second active pattern AP2. For example, the plurality of gate structures GS may be placed to intersect (overlap in the first direction D1) the first active pattern AP1 and the second active pattern AP2.

According to some example embodiments, the gate electrode 71 may be arranged to extend in the third direction D3. The gate electrode 71 may be placed between the first source/drain pattern 110 and the second source/drain pattern 210 (in the second direction D2). Adjacent gate electrodes 71 may be arranged spaced apart from each other in the second direction D2.

According to some example embodiments, the gate electrode 71 may be (electrically) connected to a gate contact 81. The gate electrode 71 may include a conductive material. In the present disclosure, the conductive material may include, for example, a metal, a metal alloy, a conductive metal nitride, a metal silicide, a doped semiconductor material, a conductive metal oxide, and/or a conductive metal oxynitride. For example, the conductive material may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), Osmium (Os), silver (Ag), gold (Au), zinc (Zn), and/or vanadium (V). However, the present disclosure is not limited thereto. The conductive metal oxide and conductive metal oxynitride may include oxidized forms of the above-described substances, but the present disclosure is not limited thereto.

According to some example embodiments, the gate electrode 71 may be placed on both sides (e.g., opposite sides in the second direction D2) of the first source/drain pattern 110, and may be placed on both sides (e.g., opposite sides in the second direction D2) of the second source/drain pattern 210. At least one of the gate electrodes 71 may be the gate electrode 71 used as a gate of a transistor. In some embodiments, some of the gate electrodes 71 may be dummy electrodes.

According to some example embodiments, the gate insulating film 72 may extend around (e.g., cover) at least a portion of the gate electrode 71. The gate insulating film 72 may include an insulating material. In the present disclosure, the insulating material may include, for example, silicon oxide, silicon-germanium oxide, germanium oxide, silicon oxynitride, silicon nitride, a high-k material having a dielectric constant greater (higher) than silicon oxide, and/or a low-k material having a dielectric constant less (lower) than silicon oxide. The high-k material may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. However, the high-k material is not limited thereto. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), and/or polyimide nanofoams such as polypropylene oxide, carbon doped silicon oxide (CDO), organo silicate glass (OSG), SiLK, amorphous fluorinated carbon, silica aerogels, silica xerogels, and/or mesoporous silica. However, the low-k material is not limited thereto.

According to some example embodiments, the gate insulating film 72 may include different insulating materials. For example, the drawing illustrates that the gate insulating film 72 is a single film, but it is only for convenience of explanation, and the gate insulating film 72 may include a plurality of films. Even though the drawing illustrates a single layer of the gate insulating film 72, the gate structure GS may include a spacer (not illustrated) positioned on the side (e.g., a side surface) of the gate structure GS.

According to some example embodiments, the first source/drain pattern 110 and the second source/drain pattern 210 may disposed on opposite sides of the gate structure GS (e.g., one of the gate structures GS). For example, the first source/drain pattern 110 may be disposed on a first side of the gate structure GS, and the second source/drain pattern 210 may be disposed on a second side that is opposite the first side of the gate structure GS (in the second direction D2). For example, at least one of the gate structures GS may be between the first source/drain pattern 110 and the second source/drain pattern 210 in the second direction D2.

According to some example embodiments, the first source/drain pattern 110 and the second source/drain pattern 210 may have the same conductivity type. For example, the first source/drain pattern 110 and the second source/drain pattern 210 may have an N-type or a P-type. In an example embodiment, the first source/drain pattern 110 and the second source/drain pattern 210 may have different conductivity types. For example, either the first source/drain pattern 110 or the second source/drain pattern 210 may have the N-type, and the other one may have the P-type. In an example embodiment, each of the first source/drain pattern 110 and the second source/drain pattern 210 may include impurities, and the impurities may vary depending on the conductivity type. For example, the N-type may include an N-type dopant, which is an impurity, such as phosphorus (P), arsenic (As), antimony (Sb) and/or bismuth (Bi), and the P-type may include a P-type dopant, which is an impurity, such as boron (B) and/or gallium (Ga).

According to some example embodiments, the semiconductor device 10 may include a frontside interlayer insulating film 50, a frontside plug (the frontside wiring via 82 and the frontside contact 83), and the gate contact 81.

According to some example embodiments, the frontside interlayer insulating film 50 may include a first frontside interlayer insulating film 51, a second frontside interlayer insulating film 52, a third frontside interlayer insulating film 53, and a gate capping layer 54. The first frontside interlayer insulating film 51 may be formed on the first source/drain pattern 110 and the second source/drain pattern 210, and the gate capping layer 54 may be formed on the gate structure GS. The second frontside interlayer insulating film 52 and the third frontside interlayer insulating film 53 may be sequentially formed on the first frontside interlayer insulating film 51 and/or the gate capping layer 54. The first frontside interlayer insulating film 51, the second frontside interlayer insulating film 52, the third frontside interlayer insulating film 53, and the gate capping layer 54 may include (e.g., may be formed of), for example, a silicon oxide layer and/or a silicon nitride layer. Each of the first frontside interlayer insulating film 51, the second frontside interlayer insulating film 52, the third frontside interlayer insulating film 53, and the gate capping layer 54 may include (e.g., may be) the same material, or may include (e.g., may be) different materials.

According to some example embodiments, the frontside plug (the frontside wiring via 82 and the frontside contact 83) may be formed in the first frontside interlayer insulating film 51 and the second frontside interlayer insulating film 52. For example, the frontside wiring via 82 may be in (may extend into) the second frontside interlayer insulating film 52. For example, the frontside contact 83 may be in (may extend into) the first frontside interlayer insulating film 51.

According to some example embodiments, the frontside plug (the frontside wiring via 82 and the frontside contact 83) may include the frontside wiring via 82 and the frontside contact 83. The frontside plug (the frontside wiring via 82 and the frontside contact 83) may be electrically connected to the second source/drain pattern 210. The frontside contact 83 may be in contact with the second source/drain pattern 210. The frontside wiring via 82 may be formed on the frontside contact 83. The frontside contact 83 and the frontside wiring via 82 may include metal materials. In some embodiments, the frontside plug (e.g., the frontside contact 83 may be in (extend into) the first frontside interlayer insulating film 51 and the second source/drain pattern 210.

According to some example embodiments, a frontside wiring pattern 41 may be on the frontside plug (the frontside wiring via 82 and the frontside contact 83). For example, the frontside wiring pattern 41 may be in (e.g., may extend into) the third frontside interlayer insulating film 53. The frontside plug (the frontside wiring via 82 and the frontside contact 83) may be (electrically) connected to the frontside wiring pattern 41. Specifically, the frontside wiring pattern 41 may be connected to (in contact with) the frontside wiring via 82. The frontside wiring pattern 41 may be one of the signal lines that transmit electrical signals to the semiconductor device 10.

According to some example embodiments, the gate contact 81 may be formed in (within) the gate capping layer 54 and the second frontside interlayer insulating film 52. For example, the gate contact 81 may extend into the gate capping layer 54 and the second frontside interlayer insulating film 52.

According to some example embodiments, the gate contact 81 may be (electrically) connected to the gate electrode 71. For example, the gate contact 81 may be connected to the gate electrode 71 (e.g., the uppermost one of the gate electrodes 71) by extending into (e.g., penetrating) a portion of the frontside interlayer insulating film 50 (e.g., the gate capping layer 54 and the second frontside interlayer insulating film 52). The gate contact 81 may include a metal material. The gate contact 81 may be (electrically) connected to a gate wiring pattern 42. The gate wiring pattern 42 may be on the gate contact 81. For example, the gate wiring pattern 42 may be in (e.g., extend into) the third frontside interlayer insulating film 53.

According to some example embodiments, the backside wiring pattern 30 may be one of the power lines that supplies power to the semiconductor device 10. The backside wiring pattern 30 may be extended in the second direction D2. The backside wiring pattern 30 may have the width in the third direction D3.

According to some example embodiments, the backside wiring pattern 30 may be placed on a backside 20b (e.g., a back surface or a lower surface) of the base pattern 20. The backside wiring pattern 30 may be (electrically) connected to the first source/drain pattern 110 via the backside plug 60. In the drawing, it is illustrated that the backside wiring pattern 30 is a single film, but example embodiments of the present are not limited thereto. For example, the backside wiring pattern 30 may include a multi-layer structure including a barrier film and a filling film.

According to some example embodiments, the backside wiring pattern 30 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), Osmium (Os), silver (Ag), gold (Au), zinc (Zn), vanadium (V), and/or combinations thereof. However, the backside wiring pattern 30 is not limited thereto.

According to some example embodiments, the semiconductor device 10 may include the backside plug 60. The backside plug 60 may extend into the base pattern 20 (e.g., may extend from the backside 20b of the base pattern 20 toward he first source/drain pattern 110) to be (electrically) connected to the first source/drain pattern 110. The backside plug 60 may include metal material. The backside plug 60 may be (electrically) connected to the backside wiring pattern 30. The backside wiring pattern 30 may be electrically connected to the first source/drain pattern 110 via the backside plug 60.

According to some example embodiments, the backside plug 60 may include a power via 61 and a backside contact 62 (on (an upper surface of) the power via 61). The power via 61 may be (electrically) connected to the backside wiring pattern 30. The power via 61 may be interfaced (may be in contact) with the backside wiring pattern 30. The width of the power via 61 in the second direction D2 may be greater than the width of the backside contact 62 in the second direction D2.

According to some example embodiments, the backside contact 62 may protrude from an upper surface of the power via 61. The backside contact 62 may be electrically connected to the power via 61. The backside contact 62 may be electrically connected to the first source/drain pattern 110. At least a portion of the backside contact 62 may contact the first source/drain pattern 110.

According to some example embodiments, the power via 61 and the backside contact 62 may include a metal material. In some embodiments, the power via 61 and the backside contact 62 may include different metal materials. For example, the resistivity of the backside contact 62 may be less than the resistivity of the power via 61. Since the resistivity of the backside contact 62 in contact with the first source/drain pattern 110 is small (e.g., less than the resistivity of the power via 61), the voltage drop may be reduced and electrical loss may be reduced. The performance of the semiconductor device 10 may be improved by improving the current transfer efficiency from the backside wiring pattern 30 to the first source/drain pattern 110. However, it is a mere example embodiment, and the characteristics of the metal material(s) included in the power via 61 and the backside contact 62 are not limited thereto.

According to some example embodiments, the backside contact 62 may include a first contact region 62a and a second contact region 62b (that is a region other than the first contact region 62a). The second contact region 62b may be (electrically) connected to (may be in contact with) the power via 61. The first contact region 62 a may be placed between the second contact region 62b and the first source/drain pattern 110 (in the first direction D1). In some embodiments, the first contact region 62a may protrude toward the first source/drain pattern 110 from the second contact region 62b in the first direction D1.

According to some example embodiments, the first source/drain pattern 110 may extend around (e.g., at least partially surround) the first contact region 62a. Since the first contact region 62a is (at least partially) surrounded by the first source/drain pattern 110, the contact area between the backside plug 60 and the first source/drain pattern 110 may increase. As the contact area between the backside plug 60 and the first source/drain pattern 110 increases, the contact resistance between the backside plug 60 and the first source/drain pattern 110 may be reduced. This may improve the current transfer efficiency from the backside wiring pattern 30 to the first source/drain pattern 110, thereby improving the performance of the semiconductor device 10.

According to some example embodiments, a first source/drain liner 120, which will be described later, may extend around (e.g., at least partially surround) the second contact region 62b. The second contact region 62b may be surrounded on the side by the first source/drain liner 120 and on the lower side by the power via 61. For example, the power via 61 may be on (e.g., in contact with) a lower surface of the second contact region 62b, and the first source/drain liner 120 may be on (e.g., in contact with) a side surface of the second contact region 62b.

According to some example embodiments, the semiconductor device 10 may include the first source/drain liner 120. At least a portion of the first source/drain liner 120 may be disposed between the first source/drain pattern 110 and the (adjacent) gate structure(s) GS (in the second direction D2), and between the first source/drain pattern 110 and the (adjacent) plurality of channel patterns CH (in the second direction D2). A portion (e.g., a remainder) of the first source/drain liner 120 may be in (e.g., may extend into) the base pattern 20. The first source/drain liner 120 may extend around (e.g., at least partially surround) the first source/drain pattern 110. The first source/drain liner 120 may be placed on the side (e.g., side surfaces) of the channel patterns CH. The first source/drain liner 120 may be on a side surface of the first source/drain pattern 110. The first source/drain liner 120 may include, for example, silicon (Si) and/or silicon germanium (SiGe), but is not limited thereto.

According to some example embodiments, at least a portion of the first source/drain liner 120 may be conformally arranged with respect to a side (e.g., side surfaces) of the plurality of channel patterns CH. For example, the boundary between the first source/drain liner 120 and the first source/drain pattern 110 may be (substantially) parallel to the boundary between the first source/drain liner 120 and the plurality of channel patterns CH.

According to some example embodiments, the outer surface of the first source/drain liner 120 and the outer surface of the first source/drain pattern 110 may have various shapes. For example, the outer surface of the first source/drain liner 120 may have a diamond shape, a circle shape, or a rectangle shape. For example, the outer surface of the first source/drain pattern 110 may have a diamond shape, a circle shape, or a rectangle shape.

According to some example embodiments, the first source/drain liner 120 may have the same conductivity type as the first source/drain pattern 110. The first source/drain liner 120 may include the same type of impurities as the first source/drain pattern 110. If the first source/drain pattern 110 has the P-type, the first source/drain liner 120 may also have the P-type. When the first source/drain pattern 110 has the N-type, the first source/drain liner 120 may also have the N-type. However, the types of boundaries and conductivity types of the first source/drain pattern 110 and the first source/drain liner 120 are not limited thereto.

The first source/drain liner 120 may have a different composition from the first source/drain pattern 110. For example, the impurity concentration of the first source/drain liner 120 may be less (lower) than the impurity concentration of the first source/drain pattern 110.

According to some example embodiments, one end 120a (e.g., an upper end 120a) of the first source/drain liner 120 (in the first direction D1) may be in contact with the frontside interlayer insulating film 50 (e.g., the first frontside interlayer insulating film 51). The one end 120a of the first source/drain liner 120 may be arranged between the plurality of channel patterns CH that are adjacent in the second direction D2. The one end 120a of the first source/drain liner 120 may be positioned farther from the backside 20b of the base pattern 20 than the other end 120b (e.g., a lower end 120b) of the first source/drain liner 120 in the first direction D1. The other end 120b of the first source/drain liner 120 may be in the base pattern 20. The other end 120b of the first source/drain liner 120 may be on (e.g., may be in contact with) the upper surface of the power via 61.

According to some example embodiments, the one end 120a of the first source/drain liner 120 may be arranged on the same planar as one end of the first source/drain pattern 110. For example, the one end 120a (e.g., an upper surface or an upper end) of the first source/drain liner 120 may be coplanar with the one end (e.g., an upper surface or an upper end) of the first source/drain pattern 110. Further, the one end 120a of the first source/drain liner 120 may be arranged on the same planar as (e.g., may be coplanar with) one side (e.g., a lower side or a lower surface) of the frontside interlayer insulating film 50 (e.g., the first frontside interlayer insulating film 51). The one end 120a of the first source/drain liner 120 may be positioned between the first source/drain pattern 110 and the (adjacent) gate structure(s) GS (in the second direction D2).

When the distance between the backside plug 60 and the (corresponding) gate structure GS (e.g., adjacent gate structure(s) GS) is close or there is no blocking member, this may increase the possibility of short circuits or currents leakage. Accordingly, the first source/drain liner 120 may be placed between the (corresponding) gate structure GS (e.g., adjacent gate structure(s) GS) and the backside plug 60. However, the present disclosure is not limited thereto, and a blocking member such as an insulating material may be further placed between the (corresponding) gate structure GS (e.g., adjacent gate structure(s) GS) and the backside plug 60.

According to some example embodiments, the other end 120b of the first source/drain liner 120 may be positioned in (within) the base pattern 20. The first source/drain liner 120 may be placed between the base pattern 20 and the backside plug 60. For example, the other end 120b of the first source/drain liner 120 may be between the base pattern 20 and the backside plug 60. The other end 120b of the first source/drain liner 120 may be positioned between the frontside 20a of the base pattern 20 and the backside 20b of the base pattern 20. For example, the other end 120b of the first source/drain liner 120 may be on (may be in contact with) an upper surface of the backside plug 60 (e.g., the power via 61).

According to some example embodiments, the other end 120b of the first source/drain liner 120 may be located closer to the backside 20b of the base pattern 20 than the (corresponding) gate structure GS (e.g., adjacent gate structure(s) GS). The distance between the other end 120b of the first source/drain liner 120 and the backside 20b of the base pattern 20 (in the first direction D1) may be less than the distance between the (corresponding) gate structure GS (e.g., adjacent gate structure(s) GS) and the backside 20b of the base pattern 20 (in the first direction D1). The distance between the other end 120b of the first source/drain liner 120 and the backside 20b of the base pattern 20 (in the first direction D1) may be less than the width (thickness) of the base pattern 20 in the first direction D1.

According to some example embodiments, the other end 120b of the first source/drain liner 120 may be positioned between the (corresponding) gate structure GS (e.g., adjacent gate structure(s) GS) and the power via 61 in the first direction D1. The other end 120b of the first source/drain liner 120 may be placed between the gate insulating film 72 at the lowest part of the (corresponding) gate structure GS (e.g., adjacent gate structure(s) GS) and one side of the power via 61. For example, the other end 120 b of the first source/drain liner 120 may be between the lowest one of the gate insulating films 72 and the power via 61 (in the first direction D1). The other end 120b of the first source/drain liner 120 may be positioned at the middle area (e.g., the middle point) of the backside contact 62 in the first direction D1. However, the shape and arrangement of the first source/drain liner 120 are not limited thereto.

According to some example embodiments, the first source/drain liner 120 may be disposed on a side of the first source/drain pattern 110 and on a side of the backside contact 62. The first source/drain liner 120 may overlap the first source/drain pattern 110 and the backside contact 62 in the second direction D2. The first source/drain liner 120 may overlap the first contact region 62a and the second contact region 62b in the second direction D2. The other end 120b of the first source/drain liner 120 may be (substantially) coplanar with the lower surface (e.g., the bottom) of the backside contact 62 in the first direction D1.

According to some example embodiments, the semiconductor device 10 may include the second source/drain liner 220. At least a portion of the second source/drain liner 220 may be positioned between the second source/drain pattern 210 and the (corresponding) gate structure GS (e.g., adjacent gate structure(s) GS) (in the second direction D2), and between the second source/drain pattern 210 and the plurality of channel patterns CH (in the second direction D2). The other portion of the second source/drain liner 220 may be positioned in (within) the base pattern 20. The second source/drain liner 220 may extend around (e.g., at least partially surround) the second source/drain pattern 210. The second source/drain liner 220 may be arranged on the side(s) (e.g., side surfaces) of the channel pattern(s) CH. The second source/drain liner 220 may include, for example, silicon (Si) and/or silicon germanium (SiGe), but the second source/drain liner 220 is not limited thereto.

According to some example embodiments, at least a portion of the second source/drain liner 220 may be conformally arranged with respect to a side (e.g., side surfaces) of the plurality of channel patterns CH. The boundary between the second source/drain liner 220 and the second source/drain pattern 210 may be (substantially) parallel to the boundary between the second source/drain liner 220 and the plurality of channel patterns CH.

According to some example embodiments, the outer surface of the second source/drain liner 220 and the outer surface of the second source/drain pattern 210 may have various shapes. For example, the outer surface of the second source/drain liner 220 may have a diamond shape, a circle shape, or a rectangle shape. For example, the outer surface of the second source/drain pattern 210 may have a diamond shape, a circle shape, or a rectangle shape.

According to some example embodiments, the second source/drain liner 220 may have the same conductivity type as the second source/drain pattern 210. The second source/drain liner 220 may include the same type of impurities as the second source/drain pattern 210. When the second source/drain pattern 210 has the P-type, the second source/drain liner 220 may also have the P-type. When the second source/drain pattern 210 has the N-type, the second source/drain liner 220 may also have the N-type. However, the types of boundaries and conductivity types of the second source/drain pattern 210 and the second source/drain liner 220 are not limited thereto.

The second source/drain liner 220 may have a different composition from the second source/drain pattern 210. For example, the impurity concentration of the second source/drain liner 220 may be less (lower) than the impurity concentration of the second source/drain pattern 210.

According to some example embodiments, one end 221 (e.g., an upper end or an upper surface) of the second source/drain liner 220 (in the first direction D1) may be in contact with the frontside interlayer insulating film 50 (e.g., the first frontside interlayer insulating film 51). The one end 221 of the second source/drain liner 220 may be arranged between the plurality of channel patterns CH that are adjacent in the second direction D2. The one end 221 of the second source/drain liner 220 may be positioned farther from the backside 20b of the base pattern 20 than the other end 222 (e.g., a lower end or a lower surface) of the second source/drain liner 220 (in the first direction D1).

According to some example embodiments, the other end 222 (e.g., the lower end or the lower surface) of the second source/drain liner 220 may face the backside 20b of the base pattern 20. The other end 222 of the second source/drain liner 220 may be arranged on the opposite side of the one end 221 (e.g., the upper end or the upper surface) of the second source/drain liner 220 (in the first direction D1). The other end 222 of the second source/drain liner 220 may include the closest part of the second source/drain liner 220 to the backside 20b of the base pattern 20.

According to some example embodiments, the second source/drain liner 220 may be positioned on a side (e.g., a side surface) of the second source/drain pattern 210 and on a side (e.g., a side surface) of a second place holder 320, which will be described in detail below. The second source/drain liner 220 may be on (e.g., cover or overlap) a lower surface (e.g., a lower end) of the second place holder 320. The second source/drain liner 220 may extend around (e.g., at least partially surround) the second source/drain pattern 210 and the second place holder 320. The second source/drain liner 220 may overlap the second source/drain pattern 210 and the second place holder 320 in the second direction D2. The second source/drain liner 220 may overlap the second source/drain pattern 210 and the second place holder 320 in the first direction D1. The second source/drain liner 220 may overlap the backside plug 60 in the second direction D2. The second source/drain liner 220 may overlap the first contact region 62 a, the second contact region 62 b, and the power via 61 in the second direction D2.

According to some example embodiments, the first source/drain liner 120 and the second source/drain liner 220 may have the same conductivity type. For example, the first source/drain liner 120 and the second source/drain liner 220 may have the N-type or may have the P-type. In an example embodiment, the first source/drain liner 120 and the second source/drain liner 220 may have different conductivity types. For example, one of the first source/drain liner 120 and the second source/drain liner 220 may have the N-type, and the other may have the P-type. In an example embodiment, the first source/drain liner 120 and the second source/drain liner 220 may each include impurities, and the impurities may vary depending on the conductivity type. For example, the N-type may include an N-type dopant, which is an impurity including, for example, phosphorus (P), arsenic (As), antimony (Sb) and/or bismuth (Bi), and the P-type may include a P-type dopant, which is an impurity including, for example, boron (B) and/or gallium (Ga).

According to some example embodiments, the semiconductor device 10 may include the second place holder 320. The second place holder 320 may be placed inside the second source/drain liner 220. The second place holder 320 may be (electrically) connected to the second source/drain pattern 210. For example, the second source/drain pattern 210 may be on (an upper surface) of the second place holder 320.

According to some example embodiments, at least a part of the second place holder 320 may be surrounded by the second source/drain pattern 210 and the second source/drain liner 220. The second place holder 320 may be placed underneath the second source/drain pattern 210. The second source/drain liner 220 may be placed between the second place holder 320 and the (corresponding) gate structure(s) GS (e.g., adjacent gate structure(s)).

According to some example embodiments, the second place holder 320 may include impurities. The second place holder 320 may include silicon (Si) and/or silicon germanium (SiGe), but the second place holder 320 may is not limited thereto.

According to some example embodiments, the impurity concentration of the second place holder 320 may be less (lower) than the impurity concentration of the second source/drain pattern 210. The impurity concentration of the second place holder 320 may be greater (higher) than the impurity concentration of the second source/drain liner 220.

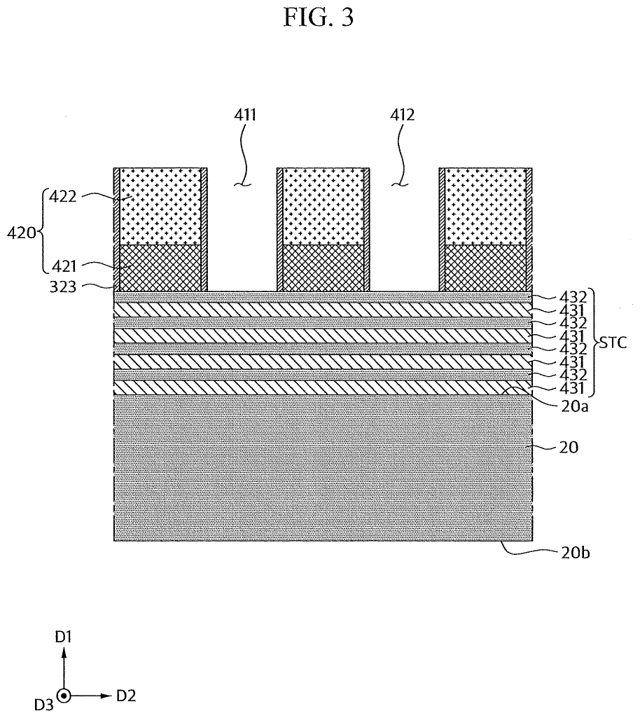

FIGS. 3-16 are drawings illustrating intermediate operations for explaining a method of manufacturing a semiconductor device according to an example embodiment. With respect to FIGS. 3-16, descriptions of the same configuration as in FIG. 2 may be briefly explained or omitted.

Referring to FIG. 3, the base pattern 20 may have the frontside 20a (e.g., an upper side 20a or an upper surface 20a) of the base pattern 20 and the backside 20b (e.g., a lower side 20b or a lower surface 20b) of the base pattern 20. The base pattern 20 may be a substrate, an insulating layer, or an insulating substrate.

According to some example embodiments, a semiconductor stacked pattern STC may be formed by alternately stacking first semiconductor layers 431 and second semiconductor layers 432 on the base pattern 20. The first semiconductor layers 431 may be sacrificial semiconductor layers, and the second semiconductor layers 432 may be semiconductor layers for channels (e.g., the plurality of channel patterns CH in FIG. 2). Even though it is illustrated that four first semiconductor layers 431 and four second semiconductor layers 432 are formed, the present disclosure is not limited thereto.

According to some example embodiments, the semiconductor stacked pattern STC may be formed on the frontside of the substrate (e.g., the base pattern 20). The first semiconductor layer 431 and the second semiconductor layer 432 may be formed by an epitaxial growth method. The first semiconductor layer 431 and the second semiconductor layer 432 may include different semiconductor materials. For example, the first semiconductor layer 431 may include silicon germanium (SiGe), and the second semiconductor layer 432 may include silicon (Si). However, the present disclosure is not limited thereto.

According to some example embodiments, during the manufacturing process of the semiconductor device 10, mask patterns 420 that are spaced apart from each other (in the second direction D2) may be formed on the semiconductor stacked pattern STC. A first opening 411 and a second opening 412 may be formed between adjacent mask patterns 420. The mask patterns 420 may include a dummy gate pattern 421 on the semiconductor stacked pattern STC and a capping pattern 422 on the dummy gate pattern 421. In some embodiments, a pre-gate spacer 323 may be formed on (a side surface of) the mask pattern 420. In some embodiments, the capping pattern 422 may be on (the upper surface of) the dummy gate pattern 421. The pre-gate spacer 323 may extend around (e.g., at least partially surround) the mask patterns 420. For example, the pre-gate spacer 323 may overlap the dummy gate pattern 421 and the capping pattern 422 in the second direction D2 and/or the third direction D3.

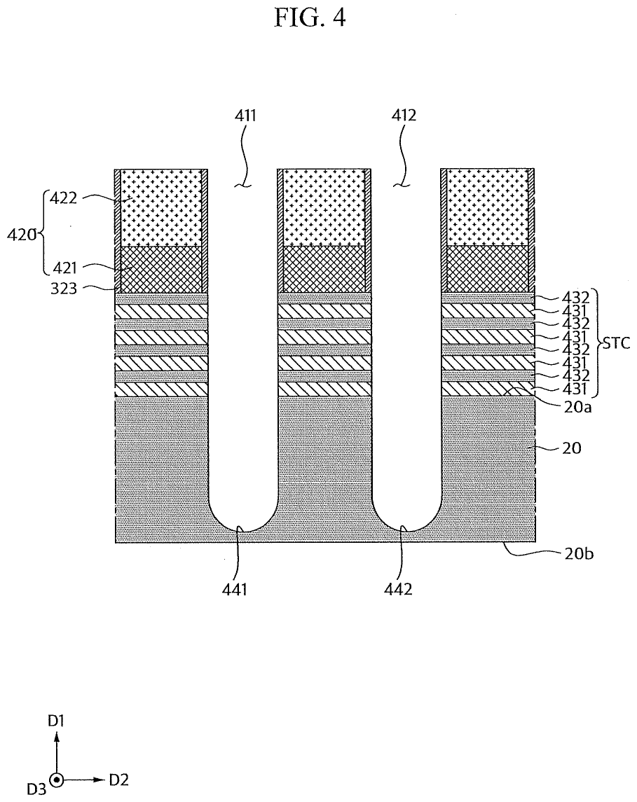

Referring to FIG. 4, the semiconductor stacked pattern STC and the base pattern 20 may be etched using the mask patterns 420 as an etching mask. As the semiconductor stacking pattern STC is etched, a plurality of semiconductor patterns stacked along the first direction D1 may be formed.

According to some example embodiments, as the semiconductor stacked pattern STC and the base pattern 20 are etched, a first source/drain opening 441 connected to the first opening 411 and a second source/drain opening 442 connected to the second opening 412 may be formed. The first source/drain opening 441 and the second source/drain opening 442 may be formed below the frontside 20a of the base pattern 20. Herein, the first and second openings 411 and 412 may be in the mask pattern 420 (e.g., may overlap the mask pattern 420 in the second and/or third directions D2 and/or D3), and the first and second source/drain openings 441 and 442 may be in the semiconductor stacked pattern STC and the base pattern 20 (e.g., may overlap the semiconductor stacked pattern STC and the base pattern 20 in the second and/or third directions D2 and/or D3).

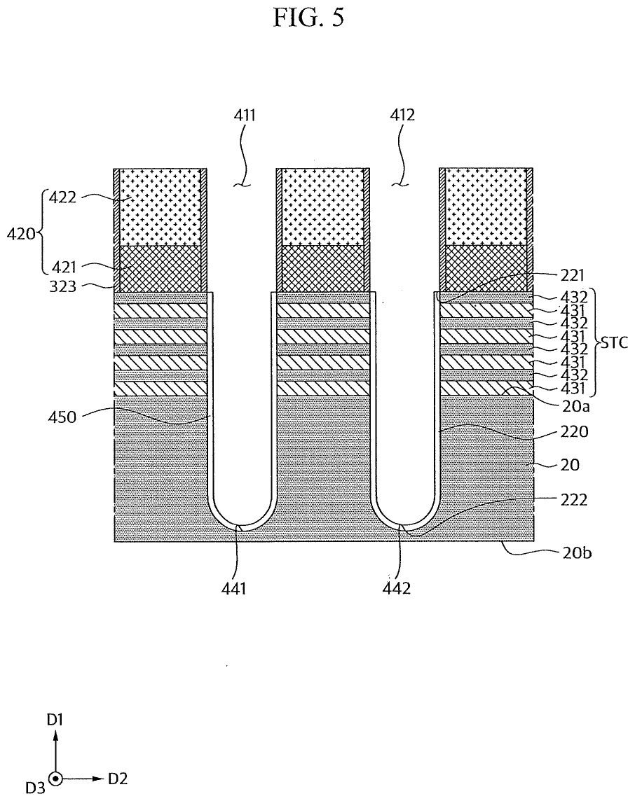

Referring to FIG. 5, a pre-first source/drain liner 450 may be formed in the first source/drain opening 441, and the second source/drain liner 220 may be formed in the second source/drain opening 442. Hereinafter, the term “pre” may indicate an intermediate structure before being formed into a final structure.

According to some example embodiments, the pre-first source/drain liner 450 may be grown via an epitaxial growth method. The second source/drain liner 220 may be grown via the epitaxial growth method. The pre-first source/drain liner 450 and the second source/drain liner 220 may grow separately or simultaneously.

According to some example embodiments, the pre-first source/drain liner 450 may be an epitaxial layer having a predetermined thickness from the edge of the first source/drain opening 441. At least a portion of the pre-first source/drain liner 450 may be in contact with the base pattern 20. The pre-first source/drain liner 450 may be formed in a shape having a predetermined thickness from the edge of the first source/drain opening 441.

According to some example embodiments, the second source/drain liner 220 may be an epitaxial layer having a predetermined thickness from the edge of the second source/drain opening 442. At least a portion of the second source/drain liner 220 may be in contact with the base pattern 20. The second source/drain liner 220 may be formed in a shape having a predetermined thickness from the edge of the second source/drain opening 442.

According to some example embodiments, the pre-first source/drain liner 450 and the second source/drain liner 220 may include silicon (Si) and/or silicon germanium (SiGe). However, the pre-first source/drain liner 450 and the second source/drain liner 220 are not limited thereto.

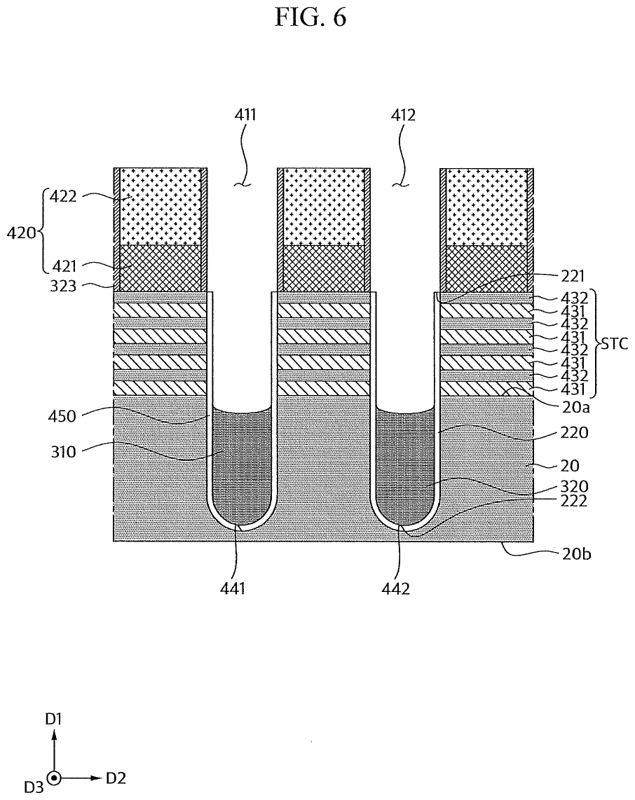

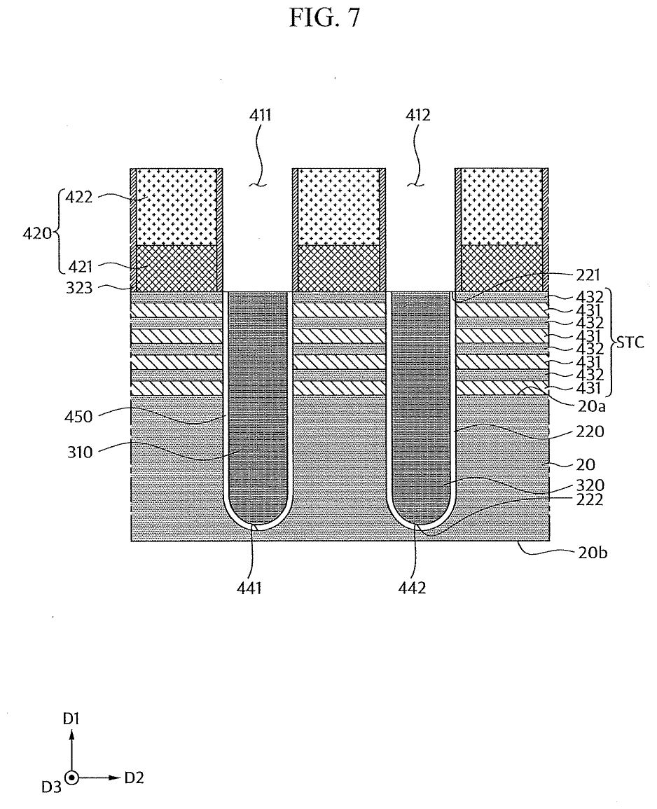

After the manufacturing process of FIG. 5, either of the manufacturing processes of FIG. 6 and FIG. 7 may be selectively performed.

Referring to FIG. 6, a first place holder 310 may be formed in a (lower) part of the first source/drain opening 441. The second place holder 320 may be formed in a (lower) part of the second source/drain opening 442. At least a portion of the first place holder 310 and at least a portion of the second place holder 320 may be formed in (within) the base pattern 20.

According to some example embodiments, the first place holder 310 may be formed by selectively epitaxially growing a semiconductor material in some region within the first source/drain opening 441, and the second place holder 320 may be formed by selectively epitaxially growing a semiconductor material in some region within the second source/drain opening 442.

Referring to FIG. 7, the first place holder 310 may be formed in the first source/drain opening 441. The second place holder 320 may be formed in the second source/drain opening 442. At least a portion of the first place holder 310 and at least a portion of the second place holder 320 may be formed in (within) the interior of the base pattern 20 and the interior of the semiconductor stacked pattern STC. For example, the first place holder 310 and the second place holder 320 may overlap the base pattern 20 and the semiconductor pattern STC in the second direction D2 and/or the third direction D3.

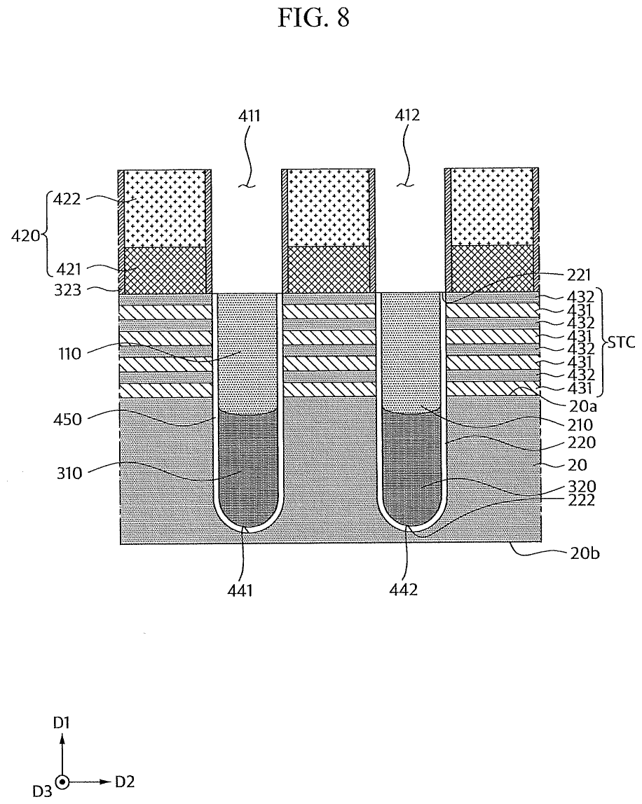

Referring to FIG. 8, after the process of FIG. 6 or FIG. 7, the first source/drain pattern 110 may be formed in the first source/drain opening 441, and the second source/drain pattern 210 may be formed in the second source/drain opening 442. The first source/drain pattern 110 may be on (an upper surface of) the first place holder 310, and the second source/drain pattern 210 may be on (an upper surface of) the second place holder 320. When the process of FIG. 7 is chosen, a portion (e.g., an upper portion) of the first place holder 310 and a portion (e.g., an upper portion) of the second place holder 320 may be removed before forming the first source/drain pattern 110 and the second source/drain pattern 210 thereon, respectively.

According to some example embodiments, the first source/drain liner 120, the first place holder 310 and the first source/drain pattern 110 may be formed from below (in or within) the first source/drain opening 441. The second source/drain liner 220, the second place holder 320, and the second source/drain pattern 210 may be formed from below (in or within) the second source/drain opening 442. The first source/drain pattern 110 and the second source/drain pattern 210 may be formed on the place holder (e.g., formed on the first place holder 310 and the second place holder 320, respectively).

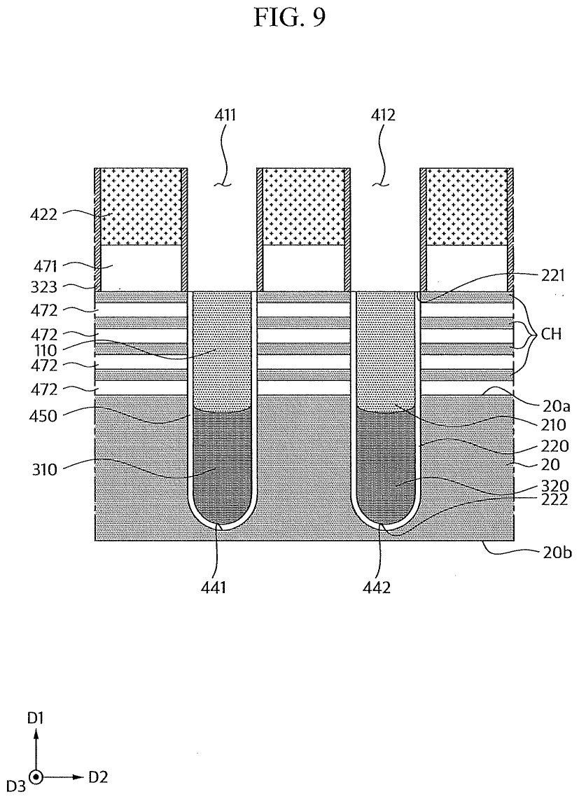

Referring to FIG. 9, the plurality of channel patterns CH that are spaced apart from each other (in the first direction D1) may be formed by selectively removing the first semiconductor layers 431 of the semiconductor stacked pattern STC and the dummy gate pattern 421. Openings 471 and 472 may be formed on the uppermost one of the plurality of channel patterns CH and between adjacent ones of the plurality of channel patterns CH, respectively. The openings 471 and 472 may be spaces from which the dummy gate pattern 421 and the first semiconductor layers 431 of the semiconductor stacked pattern STC have been removed, respectively.

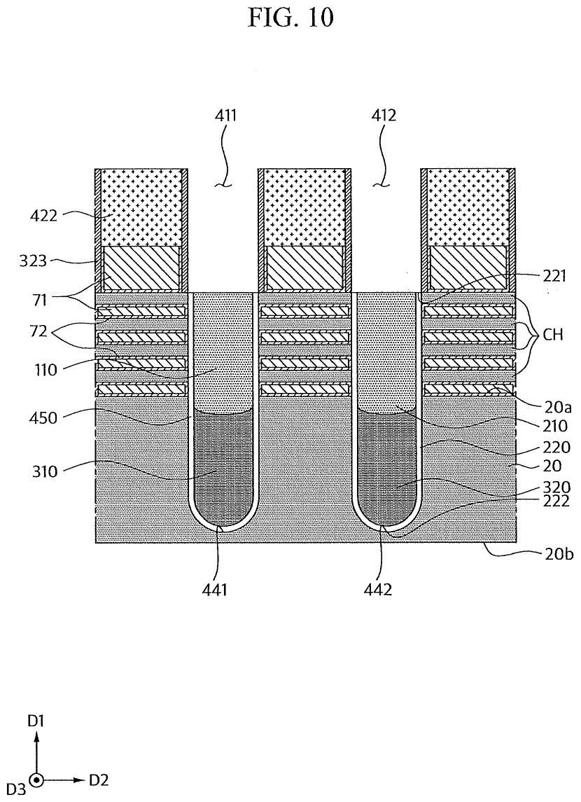

Referring to FIG. 10, the gate electrode 71 may be formed between adjacent ones of the plurality of channel patterns CH and on the uppermost one of the plurality of channel patterns CH. The gate insulating film 72 may be formed between (adjacent ones) the plurality of channel patterns CH and the gate electrode 71.

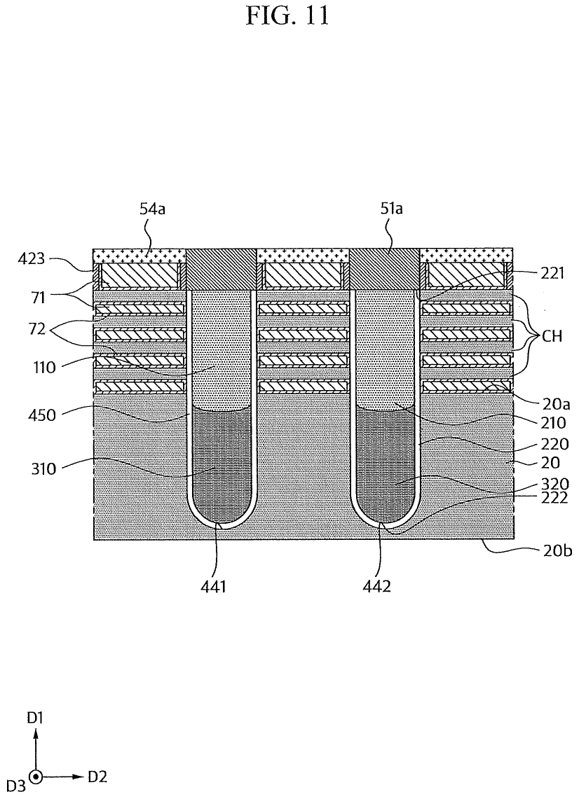

Referring to FIG. 11, a pre-first frontside interlayer insulating film 51a may be formed on the first source/drain pattern 110 and the second source/drain pattern 210. In the process of forming the pre-gate capping layer 54a, and the gate spacer 423, at least a portion of the capping pattern 422 and at least a portion of the pre-gate spacer 323 may be removed (e.g., etched). The gate structure GS may include the gate electrode 71, the gate insulating film 72, and the gate spacer 423. The pre-gate capping layer 54a may be on the gate structure GS.

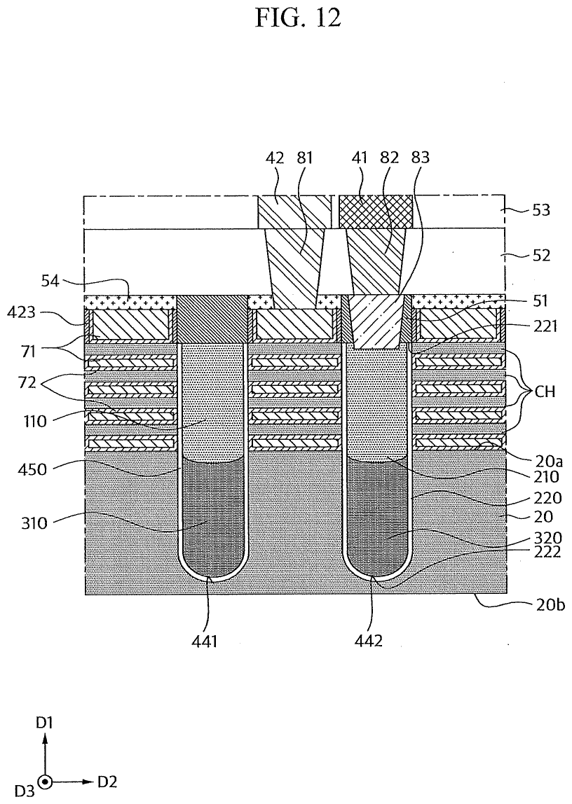

Referring to FIG. 12, a portion of the pre-first frontside interlayer insulating film 51a may be removed (e.g., etched) to form the first frontside interlayer insulating film 51, and a portion of the pre-gate capping layer 54a may be removed (e.g., etched) to form the gate capping layer 54. A portion of the first frontside interlayer insulating film 51 may form an opening for the frontside plug (e.g., the frontside wiring via 82 and the frontside contact 83) exposing the second source/drain pattern 210. The frontside contact 83 may be formed in (within) the opening for the frontside plug. The frontside contact 83 may be electrically connected to the second source/drain pattern 210.

According to some example embodiments, the second frontside interlayer insulating film 52 may be formed on the first frontside interlayer insulating film 51 and the gate capping layer 54. The frontside wiring via 82 may be formed to extend into (e.g., penetrate) the second frontside interlayer insulating film 52. The gate contact 81 may be formed to extend into (e.g., penetrate) the gate capping layer 54 and the second frontside interlayer insulating film 52.

According to some example embodiments, the third frontside interlayer insulating film 53 may be formed on the second frontside interlayer insulating film 52. In (within) the third frontside interlayer insulating film 53, the gate wiring pattern 42 (electrically) connected to the gate contact 81 and the frontside wiring pattern 41 (electrically) connected to a frontside plug (the frontside wiring via 82 and the frontside contact 83) may be formed. The gate wiring pattern 42 may be electrically connected to (the uppermost one of) the gate electrodes 71 of the gate structure GS via the gate contact 81.

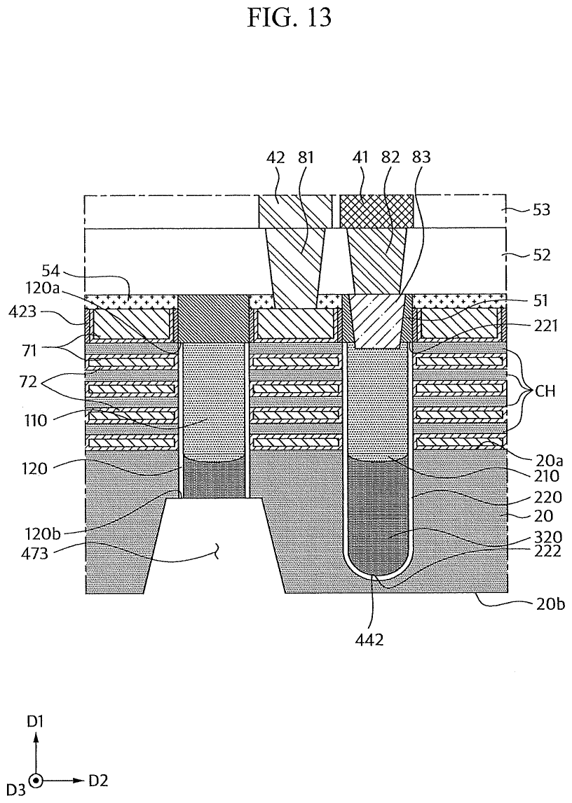

In FIG. 13 to FIG. 16, and below, although not illustrated, the manufacturing process may be performed after flipping the structure of FIG. 12 by 180 degrees.

Referring to FIG. 13, a portion of the base pattern 20, a portion of the first place holder 310, and a portion of the pre-first source/drain liner 450 may be removed (e.g., etched) to form a first hole 473 for the power via 61 and the first source/drain liner 120.

According to some example embodiments, the first hole 473 for the power via 61 may expose the first place holder 310 and the first source/drain liner 120. The lower end of the first hole 473 of the power via 61 may be placed on the same planar as (may be coplanar with) the backside 20b of the base pattern 20.

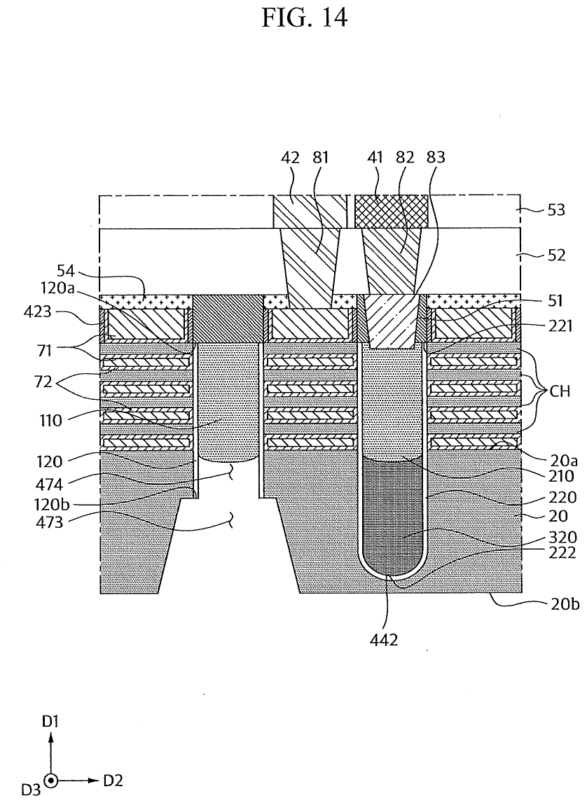

Referring to FIG. 14, a second hole 474 for the second contact region 62b may be formed by removing (e.g., etching away) the entire first place holder 310 remaining after the process of FIG. 13. The lower end of the second hole 474 for the second contact region 62b may be arranged on the same planar as (may be coplanar with) the upper end of the first hole 473 for the power via 61. The second hole 474 for the second contact region 62 b may expose the first source/drain pattern 110.

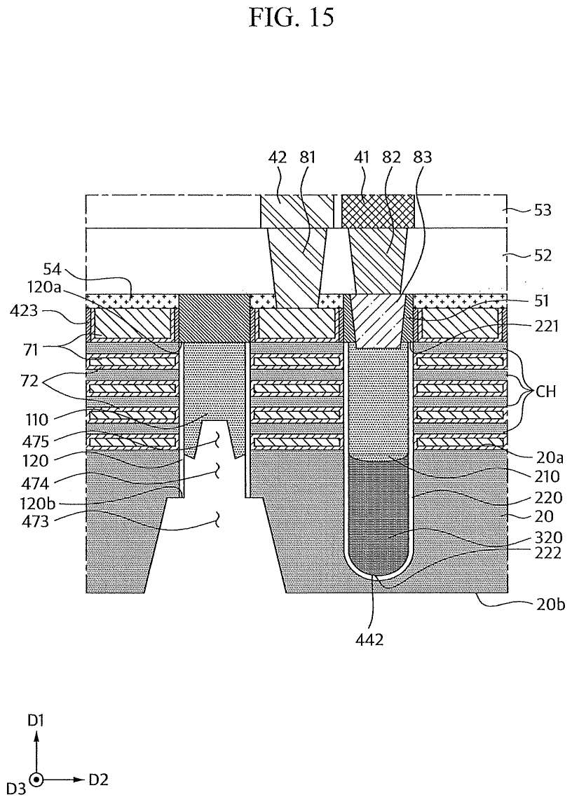

Referring to FIG. 15, a third hole 475 for the first contact region 62a may be formed by removing (e.g., etching) a portion of the first source/drain pattern 110 exposed by the second hole 474 for the second contact region 62b. The lower end of the third hole 475 of the first contact region 62a may be arranged on the same planar as (may be coplanar with) a part of the upper end of the second hole 474 for the second contact region 62b. The third hole 475 for the first contact region 62a may increase the area where the first source/drain pattern 110 is exposed compared to the case of FIG. 14.

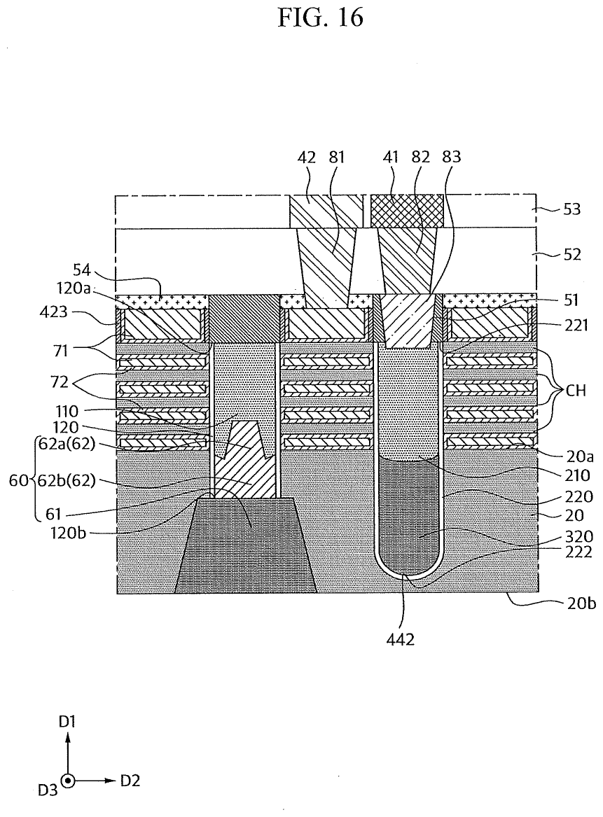

Referring to FIG. 16, the backside plug 60 may be formed in the third hole 475, the second hole 474, and the first hole 473. The backside plug 60 may include (e.g., may be formed of) a metal layer. The backside plug 60 may include the power via 61 and the backside contact 62 that are integrally connected to form a monolithic structure.

According to some example embodiments, the first contact region 62a may be formed in the third hole 475. The second contact region 62b may be formed in the second hole 474. The power via 61 may be formed in the first hole 473. The power via 61, the second contact region 62b, and the first contact region 62a may extend in the first direction D1 (from the backside 20b of the base pattern 20 toward the first source/drain pattern 110).

According to some example embodiments, the backside contact 62 and the power via 61 may include different metal materials. However, the present disclosure is not limited thereto. The backside contact 62 and the power via 61 may be formed simultaneously and may have the same material.

According to some example embodiments, referring to FIG. 2, the backside wiring pattern 30 may be formed on the backside 20b of the base pattern 20 and the backside plug 60.

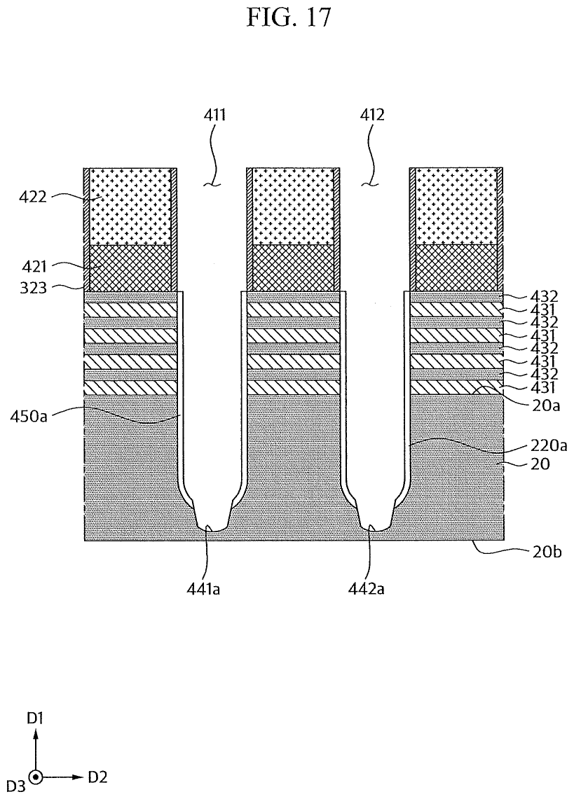

FIGS. 17-19 are drawings illustrating intermediate operations for explaining a method of manufacturing the semiconductor device 10a according to some example embodiments. The semiconductor device 10a may be (substantially) similar to the semiconductor device 10. Descriptions of the same configuration of the semiconductor device 10 in FIG. 2 may be briefly explained or omitted.

Referring to FIG. 17, after the process of FIG. 4, a pre-first source/drain liner 450a may be formed on at least a portion of the rim (e.g., inner surface) of the first source/drain opening 441a. A second source/drain liner 220a may be formed on at least a portion of the rim (e.g., inner surface) of the second source/drain opening 442a. For example, the pre-first source/drain liner 450a and the second source/drain liner 220a may be formed by removing (e.g., etching) portions of the pre-first source/drain liner 450, the second source/drain liner 220, and (at least a portion of) the base pattern 20 in the first direction D1 after the process(es) of FIG. 5.

According to some example embodiments, the pre-first source/drain liner 450a may be formed by depositing a semiconductor material on at least a portion of the rim (e.g., inner surface) of a first source/drain opening 441a after the process of FIG. 4. In some embodiments, the pre-first source/drain liner 450a may be formed by removing (e.g., etching) a lower portion (e.g., the bottom) of the pre-first source/drain liner 450 after the process of FIG. 5. The second source/drain liner 220a may be formed in a similar manner (e.g., the same manner) as the pre-first source/drain liner 450a. For example, the second source/drain liner 220a may be formed by removing (e.g., etching) a lower portion (e.g., the bottom) of the second source/drain liner 220 in FIG. 5.

According to some example embodiments, the pre-first source/drain liner 450a may be formed only on the side wall of the first source/drain opening 441a. For example, a lower end (and a lower side wall)of the first source/drain opening 441a may be exposed. The second source/drain liner 220a may be formed only on the side wall of the second source/drain opening 442a. For example, a lower end (and a lower side wall) of the second source/drain opening 442a may be exposed.

According to some example embodiments, an opening may be formed on one side (e.g., a lower portion) of the pre-first source/drain liner 450a, thereby exposing a portion of the base pattern 20. An opening may be formed at the end (e.g., the lower end) of the pre-first source/drain liner 450a.

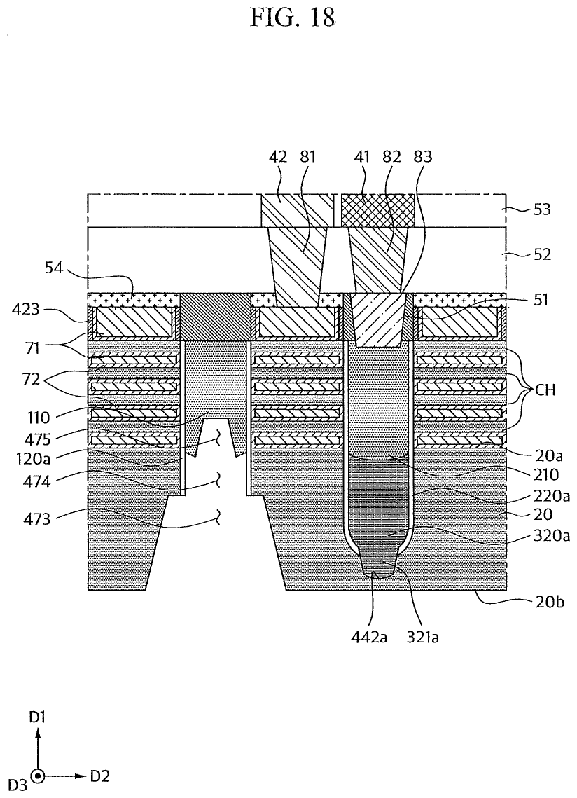

According to some example embodiments, an opening may be formed on one side (e.g., a lower portion) of the second source/drain liner 220a, thereby exposing a portion of the base pattern 20. An opening may be formed at the end (e.g., the lower end) of the second source/drain liner 220a. After the processes illustrated in FIG. 17, (substantially) the same processes to those illustrated in FIGS. 6-12 may be performed before the processes illustrated in FIG. 18.

Referring to FIG. 18, the first source/drain liner 120 may be formed by removing (e.g., etching) at least a portion of the pre-first source/drain liner 450a. The third hole 475 for the first contact region 62a, the second hole 474 for the second contact region 62b, and the first hole 473 for the power via 61 may be formed by removing (e.g., etching) a part of the pre-first source/drain pattern 450a and the first place holder 310.

According to some example embodiments, a second place holder 320a may be formed in the second source/drain opening 442a. The second place holder 320a may be formed by forming an opening at an end (e.g., lower end) of the second source/drain liner 220a. The second place holder 320a may include a protrusion 321a in the opening. The protrusion 321a may protrude lower in the first direction D1 than the lower end (e.g., bottom) of the second source/drain liner 220a. For example, the lower end of the protrusion 321a may be lower than the lower end of the second source/drain liner 220a. At least a portion of the protrusion 321a of the second place holder 320a may be in contact with the base pattern 20.

According to some example embodiments, the second source/drain pattern 210 may be formed on an upper surface (e.g., top) of the second place holder 320a. The second source/drain pattern 210 may be formed on the inner side of the second source/drain liner 220a. The second source/drain liner 220a may be electrically connected to the frontside plug (the frontside wiring via 82 and the frontside contact 83).

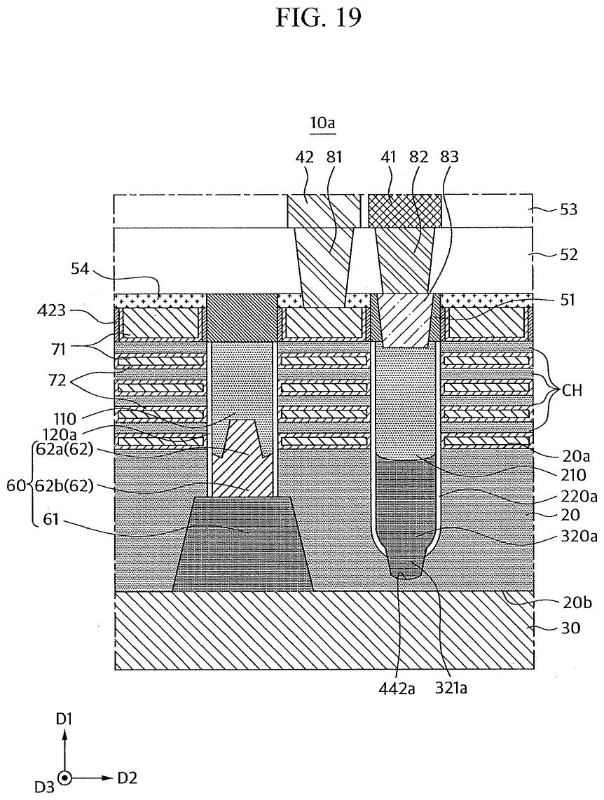

Referring to FIG. 19, the backside plug 60 may be formed in the third hole 475, the second hole 474, and the first hole 473. For example, the first contact region 62a may be in the third hole 475, the second contact region 62b may be in the second hole 474, and the power via 61 may be in the first hole 473. In some embodiments, the backside plug 60 may be electrically connected by making contact with the first source/drain pattern 110. The backside wiring pattern 30 may be formed on the backside 20b of the base pattern 20 and the backside plug 60.

At the beginning of the previously described method of manufacturing the semiconductor device 10, the base pattern 20 may include (e.g., may be formed of) a semiconductor material. For example, the base pattern 20 may include silicon and/or silicon-germanium. After the source/drain liners 120, 220, 120a, 220a, placeholders 320, 320a, and source/drain patterns 110, 210 are formed, the semiconductor material forming the base pattern 20 may be removed (via etching), and an insulating material may be formed in the region where the semiconductor material has been removed. For example, after the process of FIG. 12, the semiconductor material of the base pattern 20 may be replaced with an insulating material. This process can be similarly applied to example embodiments of FIGS. 17 to 19.

While the inventive concept has been particularly shown and described with reference to embodiments thereof, it will be understood that various changes in form and details may be made therein without departing from the scope of the following claims.

What is claimed is:

1. A semiconductor device comprising:
a base pattern;
channel patterns on a frontside of the base pattern corresponding to an upper surface of the base pattern, wherein the channel patterns are spaced apart from each other in a first direction that is perpendicular to the upper surface of the base pattern;
a gate structure on the upper surface of the base pattern, wherein the gate structure comprises a gate insulating film and a gate electrode, and at least a portion of the gate structure is between adjacent ones of the channel patterns;
a first source/drain pattern on a first side of the gate structure;
a second source/drain pattern on a second side of the gate structure that is opposite to the first side of the gate structure in a second direction that intersects the first direction, wherein the second direction is parallel with the upper surface of the base pattern;
a first source/drain liner between the first source/drain pattern and the gate structure in the second direction;
a second source/drain liner between the second source/drain pattern and the gate structure in the second direction;
a backside plug in the base pattern, wherein the backside plug is electrically connected to the first source/drain pattern; and
a place holder in the base pattern, wherein the place holder is on an inner side of the second source/drain liner,
wherein an upper end of the first source/drain liner is between the first source/drain pattern and the gate structure in the second direction, and a lower end of the first source/drain liner is between the upper surface of the base pattern and a backside of the base pattern, corresponding to a lower surface of the base pattern that is opposite to the upper surface of the base pattern in the first direction, and
wherein the upper end of the first source/drain liner is opposite to the lower end of the first source/drain liner in the first direction.

2. The semiconductor device of claim 1, wherein the place holder is in contact with the second source/drain pattern.

3. The semiconductor device of claim 2, wherein a lower end of the second source/drain pattern is in the base pattern.

4. The semiconductor device of claim 3, wherein the second source/drain pattern, the second source/drain liner, and the place holder comprise respective impurities having a first impurity concentration, a second impurity concentration, and a third impurity concentration, and
wherein the first impurity concentration is different from the second impurity concentration and the third impurity concentration, and
wherein the second impurity concentration is different from the third impurity concentration.

5. The semiconductor device of claim 1, wherein at least a portion of the place holder is in contact with the base pattern.

6. The semiconductor device of claim 5, wherein a lower end of the place holder is closer than the second source/drain liner to the lower surface of the base pattern.

7. The semiconductor device of claim 1, wherein the lower end of the first source/drain liner is closer than the gate structure to the lower surface of the base pattern.

8. The semiconductor device of claim 1, wherein the backside plug comprises:
a power via that extends from the lower surface of the base pattern toward the upper surface of the base pattern in the first direction; and
a backside contact that extends from an upper surface of the power via toward the first source/drain pattern and is electrically connected to the first source/drain pattern.

9. The semiconductor device of claim 8, wherein the lower end of the first source/drain liner is in contact with the upper surface of the power via.

10. The semiconductor device of claim 8, wherein the backside contact comprises:
a first contact region, wherein the first source/drain pattern extends around the first contact region; and
a second contact region that is a region other than the first contact region, wherein the second contact region is in contact with the first source/drain liner.

11. The semiconductor device of claim 8, wherein the backside contact has a resistivity that is less than a resistivity of the power via.

12. The semiconductor device of claim 8, wherein the power via has a first width in the second direction,
wherein the backside contact has a second width in the second direction, and
wherein the first width is greater than the second width.

13. The semiconductor device of claim 1, wherein first source/drain pattern and the first source/drain liner comprise an impurity at a first impurity concentration and a second impurity concentration, respectively, and
wherein the first impurity concentration is greater than the second impurity concentration.

14. A semiconductor device comprising:
a base pattern;
channel patterns on a frontside of the base pattern, corresponding to an upper surface of the base pattern, wherein the channel patterns are spaced apart from each other in a first direction that is perpendicular to the upper surface of the base pattern;
a gate structure on the upper surface of the base pattern, wherein the gate structure comprises a gate insulating film and a gate electrode, and at least a portion of the gate structure is between adjacent ones of the channel patterns;
a first source/drain pattern on a first side of the gate structure;
a first source/drain liner between the first source/drain pattern and the gate structure in a second direction that is parallel with the upper surface of the base pattern; and
a backside plug between a backside of the base pattern, corresponding to a lower surface of the base pattern, and the first source/drain pattern in the first direction,
wherein the lower surface of the base pattern is opposite to the upper surface of the base pattern in the first direction,
wherein the backside plug is electrically connected to the first source/drain pattern,
wherein the backside plug is in contact with the base pattern, and
wherein the first source/drain liner extends along a side wall of the gate structure and extends into the base pattern in the first direction.

15. The semiconductor device of claim 14, further comprising: an interlayer insulating film on the first source/drain pattern,
wherein an upper end of the first source/drain liner is in contact with the interlayer insulating film, and
wherein a lower end of the first source/drain liner is in the base pattern.

16. The semiconductor device of claim 14, further comprising:
a second source/drain pattern on a second side of the gate structure that is opposite to the first side of the gate structure in the second direction;
a second source/drain liner between the second source/drain pattern and the gate structure in the second direction; and
a place holder in the base pattern, wherein the place holder is on an inner side of the second source/drain liner is electrically connected to the second source/drain pattern.

17. The semiconductor device of claim 16, wherein the second source/drain pattern, the second source/drain liner, and the place holder comprise respective impurities having a first impurity concentration, a second impurity concentration, and a third impurity concentration, and
wherein third impurity concentration is less than the first impurity concentration and greater than the second impurity concentration.

18. The semiconductor device of claim 14, wherein the backside plug comprises:
a power via that extends from the lower surface of the base pattern toward the upper surface of the base pattern in the first direction; and
a backside contact that protrudes from an upper surface of the power via toward the first source/drain pattern and is electrically connected to the first source/drain pattern,
wherein a lower end of the first source/drain liner is in contact with the upper surface of the power via.

19. The semiconductor device of claim 18, wherein the backside contact comprises:
a first contact region, wherein the first source/drain pattern extends around the first contact region; and
a second contact region that is a region other than the first contact region, wherein the second contact region is in contact with the first source/drain liner.

20. A semiconductor device comprising:
a base pattern;
channel patterns on a frontside of the base pattern, corresponding to an upper surface of the base pattern, wherein the channel patterns are spaced apart from each other in a first direction that is perpendicular to the upper surface of the base pattern;
a gate structure on the upper surface of the base pattern,, wherein the gate structure is between adjacent ones of the channel patterns;
a first source/drain pattern on a first side of the gate structure;
a second source/drain pattern on a second side of the gate structure that is opposite to the first side of the gate structure in a second direction that is parallel with the upper surface of the base pattern;
a backside plug underneath the first source/drain pattern, wherein the backside plug is electrically connected to the first source/drain pattern;
a place holder underneath the second source/drain pattern, wherein the place holder is electrically connected to the second source/drain pattern;
a first source/drain liner between the first source/drain pattern and the gate structure in the second direction; and
a second source/drain liner between the second source/drain pattern and the gate structure in the second direction,
wherein the first source/drain liner overlaps the backside plug in the second direction.
